(19) United States
(12) Patent Application Publication
(10) Pub. No.: US 2018/0026029 A1
(43) Pub. Date: Jan. 25, 2018

(54) Integrated ESD Protection Circuit for GaN Based Device

(71) Applicant: Taiwan Semiconductor Manufacturing Co., Ltd., Hsin-Chu (TW)

(72) Inventors: Yu-Syuan Lin, Lukang Thownship (TW); Ming-Cheng Lin, Yilan City (TW); King-Yuen Wong, Tuen Mun (HK); Jiun-Lei Yu, Zhudong Township (TW); Chun Lin Tsai, Hsin-Chu (TW)

(21) Appl. No.: 15/215,651

(22) Filed: Jul. 21, 2016

(51) Int. Cl. H01L 27/02; H01L 49/02; H01L 27/06; H01L 29/20; H01L 29/778

(52) U.S. Cl. CPC H01L 27/0266; H01L 29/2003; H01L 29/7787; H01L 27/0605; H01L 27/0288; H01L 28/20

(57) ABSTRACT

The present disclosure relates to an electrostatic discharge (ESD) protection circuit integrated with a gallium nitride (GaN) based transistor and configured to clamp a gate input voltage of the gallium nitride (GaN) based transistor during an ESD surge event, and associated methods. In some embodiments, the ESD protection circuit includes a first ESD protection stage and a second ESD protection stage connected between a gate terminal and a source terminal of the GaN based transistor. The first ESD protection stage includes a first plurality of GaN based gate-to-source shorted transistors connected in series and further connected to a first terminal of a first resistor. The second ESD protection stage is connected to the first ESD protection stage in parallel. The second ESD protection stage comprises a first GaN based shunt transistor having a gate terminal connected to the first terminal of the first resistor.

### BACKGROUND

Gallium nitride (GaN) based devices have shown great promise in many commercial applications, especially for high frequency and high power applications. Unfortunately, GaN based devices typically exhibit very small gate to source breakdown voltages, for example being less than 10 V in some cases. Therefore, GaN based devices can suffer from gate damage because of gate voltage overshoot. Electrostatic discharge (ESD) is a sudden release of electrostatic charge which can result in high electric fields and currents within an integrated circuit and is one type of overshoot that can damage GaN based devices on integrated circuits.

### BRIEF DESCRIPTION OF THE DRAWINGS

FIG. 1 illustrates an electrostatic discharge (ESD) protection circuit integrated with a gallium nitride (GaN) based transistor in accordance with some embodiments.

FIG. 2 illustrates a graph showing protection current behaviors of the ESD protection circuit of FIG. 1 in response to a gate input voltage in accordance with some embodiments.

FIG. 3 illustrates an electrostatic discharge (ESD) protection circuit integrated with a gallium nitride (GaN) based transistor in accordance with some alternative embodiments.

FIG. 4 illustrates a graph showing protection current behaviors of the ESD protection circuit of FIG. 3 in response to a gate input voltage in accordance with some embodiments.

FIG. 5 illustrates an electrostatic discharge (ESD) protection circuit integrated with a gallium nitride (GaN) based transistor in accordance with some alternative embodiments.

FIG. 6 illustrates a graph showing protection current behaviors of the ESD protection circuit of FIG. 5 in response to a gate input voltage in accordance with some embodiments.

FIG. 7 illustrates a graph showing gate voltage and protection current behaviors of the ESD protection circuit of FIG. 5 in response to an ESD surge event in accordance with some embodiments.

FIG. 8 illustrates an electrostatic discharge (ESD) protection circuit integrated with a gallium nitride (GaN) based transistor in accordance with some alternative embodiments.

FIG. 9 illustrates a flow diagram illustrating a method of protecting a gate terminal of a GaN based transistor during an ESD surge event in accordance with some embodiments.

### DETAILED DESCRIPTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one skilled in the art, that one or more aspects described herein may be practiced with a lesser degree of these specific details. In other instances, known structures and devices are shown in block diagram form to facilitate understanding.

Compared to a silicon based MOSFET (metal-oxide-semiconductor field-effect transistor), gallium nitride (GaN) based HEMTs (high electron mobility transistors) have lower threshold voltages and smaller drain to source on resistances. On one hand, these features allow for lower gate drive power and higher current and switching frequency. On the other hand, GaN based HEMTs also have lower gate breakdown voltage, which results in their gate terminals being susceptible to damage due to voltage overshoot spikes that exceed the gate breakdown voltage. Accordingly, a gate protection circuit is desired to protect GaN based HEMTs from overshoot voltage spikes during device switching or an electrostatic discharge (ESD) surge event. Notably, simply co-packaging GaN based HEMTs and silicon based clamping diodes or circuits may not be a perfect solution, as parasitic inductance and capacitance from the package or the protection circuit itself may significantly impact the operation of the final device, especially for high frequency switching power and RF applications.

The present disclosure relates to an electrostatic discharge (ESD) protection circuit integrated with a gallium nitride (GaN) based transistor and configured to clamp a gate input voltage of the GaN based transistor during an ESD surge event, and associated methods. The ESD protection circuit is integrated and fabricated together with the GaN based transistor such that parasitic inductance and parasitic capacitance are reduced. In some embodiments, the ESD protection circuit comprises a first ESD protection stage and a second ESD protection stage connected between a gate terminal and a source terminal of the GaN based transistor. The first ESD protection stage comprises a first plurality of GaN based gate-to-source shorted transistors connected in series and further connected to a first terminal of a first resistor. The second ESD protection stage is connected in parallel with the first ESD protection stage. The second ESD protection stage comprises a first GaN based shunt transistor having a gate terminal connected to the first terminal of the first resistor. By using the ESD protection circuit, a gate input voltage of the GaN based transistor is clamped during an ESD surge event, protecting the gate terminal of the GaN based transistor from being damaged.

FIG. 1 illustrates an integrated circuit (IC) chip including an electrostatic discharge (ESD) protection circuit 100 integrated with a GaN based transistor 102 on a single semiconductor substrate in accordance with some embodiments. In some embodiments, the GaN based transistor 102 is an enhancement mode high electron mobility transistor (E-HEMT) which, in and of itself, is susceptible to damage from ESD events. As shown in FIG. 1, the ESD protection circuit 100 is connected between a gate terminal and a source terminal of the GaN based transistor 102 and is configured to protect the GaN based transistor 102 from ESD events. In some embodiments, the ESD protection circuit 100 is connected directly to an I/O pin 124 of the IC chip, or is connected to a gate driver circuit which may include a drive resistor 122.

The ESD protection circuit 100 comprises a first protection path 110 and a second protection path 116 in parallel with the first protection path 110. A first ESD protection stage 118 is arranged on the first protection path 110, and a second ESD protection stage 120 is arranged on the second protection path 116.

The first ESD protection stage 118 comprises a first plurality of GaN based gate-to-source shorted transistors 104 (e.g., 104a, 104b, 104c . . . ) connected in series. In some embodiments, a first GaN based transistor 104a has a first S/D terminal, a second S/D terminal, and a gate terminal. The first S/D terminal and gate terminal are shorted together, and these shorted terminals are connected to the gate terminal of the GaN based transistor 102. The second GaN based transistor 104b also has a first S/D terminal, a second S/D terminal, and a gate terminal, wherein the first S/D terminal and gate terminal for the second GaN based transistor 104b are shorted together. The second S/D terminal of first GaN transistor 104a is connected to the shorted first S/D terminal and gate terminal of the second GaN based transistor 104b. Similarly, the second S/D terminal of the second GaN based transistor 104b is connected to a gate terminal and a first S/D terminal of a next GaN based transistor (e.g., a third GaN based transistor 104c). It is appreciated that the number of transistors in series in the first plurality of GaN based gate-to-source shorted transistors 104 can vary depending on the application. The last transistor in the first plurality of GaN based gate-to-source shorted transistors 104 has a second S/D terminal connected to a first terminal of a first resistor 106. A second terminal of the first resistor 106 is connected to the source terminal of the GaN based transistor 102, which is coupled to a DC supply node, such as ground or VSS.

The second ESD protection stage 120 is connected in parallel with the first ESD protection stage 118. The second ESD protection stage 120 comprises a first GaN based shunt transistor 108 comprising a first S/D terminal, gate terminal, and second S/D terminal. The first S/D terminal of the GaN based shunt transistor 108 is connected to the gate terminal of the GaN based transistor 102, and a gate terminal of the GaN based shunt transistor 108 is connected to the first terminal of the first resistor 106. The second S/D terminal of the GaN based shunt transistor 108 is connected to the source terminal of the GaN based transistor 102. In some embodiments, each of the first plurality of GaN based gate-to-source shorted transistors 104 has a channel width that is smaller than a channel width of the first GaN based shunt transistor 108. More specifically, each of the first plurality of GaN based gate-to-source shorted transistors 104 may have a channel width that is 10 to 50 times smaller than a channel width of the first GaN based shunt transistor 108. This allows the first GaN based shunt transistor 108 to reliably carry a larger current than each of the GaN based gate-to-source shorted transistors 104.

During an ESD surge event, a gate input voltage having a bias peak greater than a desired operational gate voltage strikes the gate terminal of the GaN based transistor 102. Current due to the ESD surge event flows through the first ESD protection path 110 when the gate input voltage is greater than a first threshold Vt1. In some embodiments, the first trigger threshold Vt1 is a sum of thresholds of the first plurality of GaN based gate-to-source shorted transistors 104. The first plurality of GaN based gate-to-source shorted transistors 104 works as a plurality of forward diodes. When the first ESD protection path 110 is triggered, biases applied on the GaN based gate-to-source shorted transistors 104 are constant, and are equal to the thresholds of the GaN based gate-to-source shorted transistors 104. For example, the first trigger threshold Vt1 is about 6V if there are four GaN based gate-to-source shorted transistors respectively having a 1.5V threshold. A first divisional bias 112 applied on the first plurality of GaN based gate-to-source shorted transistors 104 is 6V. In some embodiments, the second ESD protection stage 120 is associated with the first ESD protection stage 118, and is configured to be controlled by a second divisional bias 114 of the first ESD protection stage 118 applied on the first resistor 106. Current due to the ESD surge event flows through the second ESD protection path 116 when the gate input voltage is greater than a second trigger threshold. The second trigger threshold is reached when the second divisional bias 114 is a threshold of the first GaN based shunt transistor 108. Still using the example given above, the second ESD protection path 116 is triggered when the gate input voltage is greater than about 7.5V, where the second divisional bias 114 applied to the first resistor 106 is greater than 1.5V, the threshold of the first GaN based shunt transistor 108. After the second ESD protection path 116 is triggered, most of the ESD charges pass through the second ESD protection stage 120. The gate input voltage is then reduced, since the on resistance of the GaN based transistor 102 is very small. The reduced gate input voltage reversely result the second divisional bias 114 of the first ESD protection stage 118, i.e., the gate bias of the first GaN based shunt transistor 108, being reduced, which may further result the first GaN based shunt transistor 108 not being fully enhanced. These transient interactions between the first ESD protection stage 118 and the second ESD protection stage 120 constitute a clamping process between the first ESD protection path 110 and the second ESD protection path 116, generating a clamped gate input voltage during the ESD surge event.

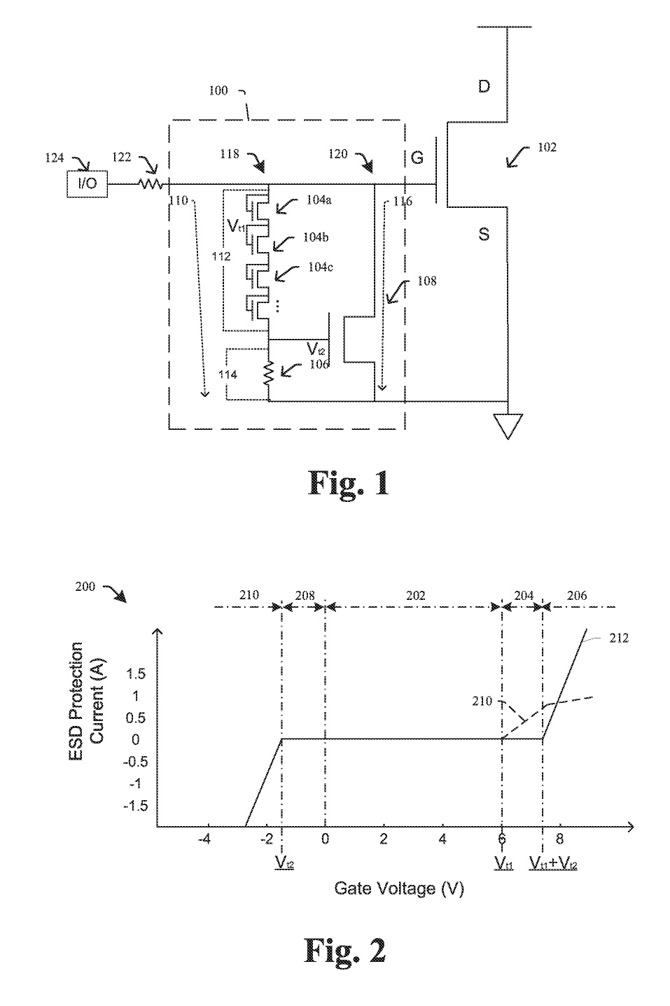

FIG. 2 illustrates a graph 200 of protection current behaviors of the ESD protection circuit 100 of FIG. 1 in response to the gate input voltage in accordance with some embodiments. As shown in FIG. 2, during a first state 202 where the gate input voltage is between zero and a first triggered threshold, transistors of ESD protection circuit 100 are in a subthreshold mode of operation and almost no ESD current flows through the ESD protection circuit 100. During a second state 204 where the gate input voltage is between the first triggered threshold and a second triggered threshold, there is some current flow through the first ESD protection path 110 (as shown by a dashed line 210) but almost no ESD current flow through the second ESD protection path 116. This is because during the second state 204, the gate input voltage is sufficient to turn on each of the first plurality of GaN based gate-to-source shorted transistors 104 and establish a non-zero voltage on the gate of the first shunt transistor 108, but this non-zero voltage established on gate of the first shunt transistor 108 is still less than the threshold voltage of the first shunt transistor 108 so the first shunt transistor remains in a subthreshold mode of operation. During a third state 206 where the gate input voltage is greater than the second triggered threshold, most of the ESD charges flow through the second ESD protection path 116 (as shown by a solid line 212). This is because during the third state 206, the gate input voltage is sufficient to turn on each of the first plurality of GaN based gate-to-source shorted transistors 104 and establish a larger non-zero voltage on the gate of the first shunt transistor 108 which is greater than a threshold voltage Vt2 of the first shunt transistor 108 so the first shunt transistor is in saturation/active mode. When the gate input voltage is negative, the first plurality of GaN based gate-to-source shorted transistors is open, and the bias drops between the gate terminal and the first S/D terminal of the first GaN based shunt transistor 108. Almost no current flows through the ESD protection circuit 100 during a fourth state 208 when the negative gate input voltage is smaller than a reverse trigger threshold. The second ESD protection stage 120 is triggered during a fifth state 210 when the negative gate input voltage is greater than the reverse trigger threshold. Corresponding to the ESD protection circuit 100 of FIG. 1, in some embodiments, the first triggered threshold is about the first threshold Vt1 of the first plurality of GaN based gate-to-source shorted transistors 104, the second triggered threshold is about a sum of the first threshold Vt1 and a second threshold Vt2 of the first GaN based shunt transistor 108, and the reverse trigger threshold is about the second threshold Vt2.

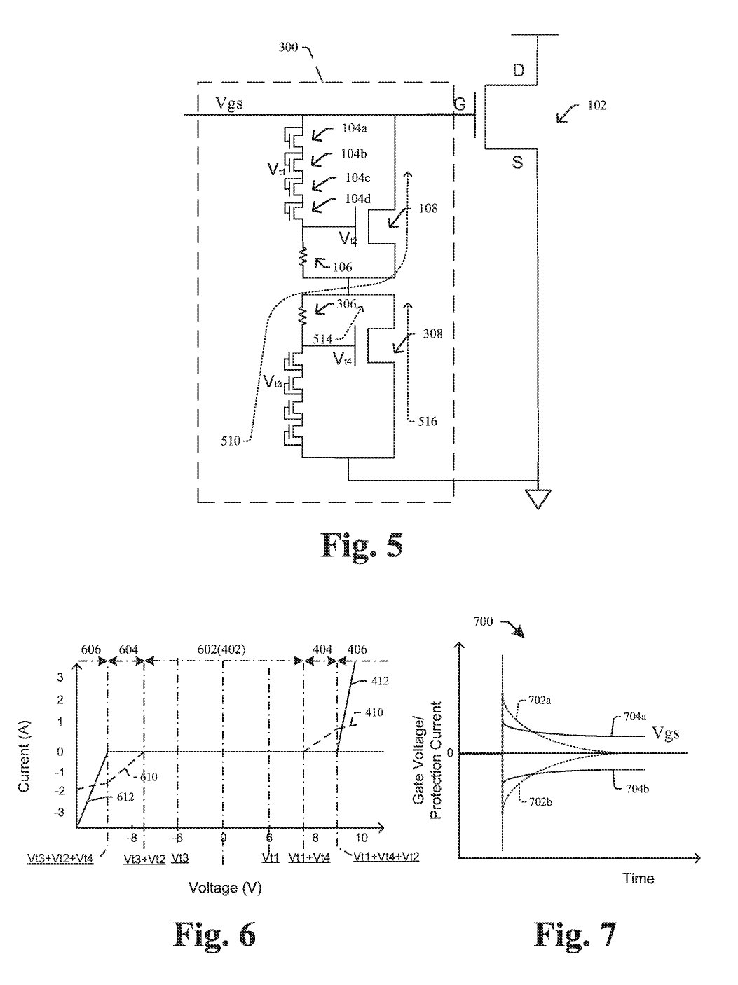

FIG. 3 and FIG. 5 illustrate an integrated circuit (IC) chip including an electrostatic discharge (ESD) protection circuit 300 integrated with a gallium nitride (GaN) based transistor 102 in accordance with some alternative embodiments. As shown in FIG. 3 or FIG. 5, the electrostatic discharge (ESD) protection circuit 300 is connected between a gate terminal and a source terminal of the GaN based transistor 102. In some embodiments, the ESD protection circuit 300 comprises a first section 302a having a similar structure as the ESD protection circuit 100 of FIG. 1, which has been described above. The ESD protection circuit 300 further comprises a second section 302b connected in series with the first section 302a, and arranged between the first section 302a and a source terminal of the GaN based transistor 102. In some embodiments, the second section 302b may have a symmetric structure with the first section 302a, and provides ESD protection for a reverse overshooting bias. The second section 302b may comprise a second plurality of GaN based gate-to-source shorted transistors 304 (e.g. 304a, 304b, 304c . . . ) connected in series. In some embodiments, a first GaN based gate-to-source shorted transistor 304a has its first S/D terminal and gate terminal shorted and connected to the source terminal of the GaN based transistor 102, and its second S/D terminal connected to a shorted gate terminal and a first S/D terminal of a second GaN based gate-to-source shorted transistor 304b. A second S/D terminal of the second GaN based gate-to-source shorted transistor 304b is further connected to a shorted gate terminal and a first S/D terminal of a next GaN based gate-to-source shorted transistor (i.e., a third GaN based gate-to-source shorted transistor 304c). The second plurality of GaN based gate-to-source shorted transistors 304 are further connected to a first terminal of a second resistor 306. A second terminal of the second resistor 306 is connected to the second terminal of the first resistor 106. The second section 302b may further comprise a second GaN based shunt transistor 308 having a first S/D terminal connected to the source terminal of the GaN based transistor 102, a gate terminal connected to the first terminal of the second resistor 306, and a second S/D terminal connected to the second S/D terminal of the first GaN based shunt transistor 108.

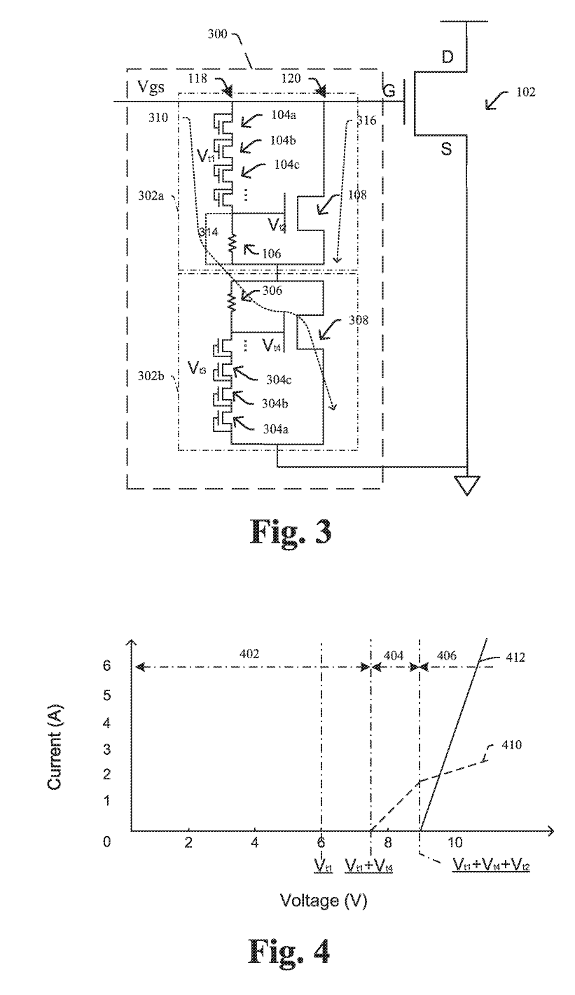

FIG. 3 and FIG. 4 show protection current paths and protection current behaviors in response to a positive gate input voltage Vgs. Almost no protection current flows through the protection circuit 300 when the gate input voltage Vgs is around a desired operational gate voltage or within a maximum allowed strike value (within a first state 402). A first ESD protection path 310 is triggered when the gate input voltage is greater than a first trigger threshold, for example, a sum of a threshold Vt1 of the first plurality of GaN based gate-to-source shorted transistors 104 and a threshold Vt4 of the second GaN based shunt transistor 308 (within a second state 404). When the first ESD protection path 310 is triggered, a first divisional bias applied on each of the GaN based gate-to-source shorted transistors 304 is equal to the threshold of each of the GaN based gate-to-source shorted transistors 304. A second divisional bias 314 is applied on the first resistor 106 and the gate terminal of the first GaN based shunt transistor 108. A second ESD protection path 316 is triggered when the second divisional bias 314 is greater than a threshold of the first GaN based shunt transistor 108, where the gate input voltage Vgs is greater than a second trigger threshold (within a third state 406). The second trigger threshold is a sum of the thresholds Vt1, Vt4 and Vt2 of the first GaN based shunt transistor 108.

FIG. 5 and FIG. 6 show protection current paths and protection current behaviors in response to a negative gate input voltage Vgs. Similar as discussed above, almost no protection current flows through the protection circuit 300 when the gate input voltage Vgs is smaller than a first trigger threshold (within a first state 602). A first ESD protection path 510 is triggered when the gate input voltage is greater than a first trigger threshold, for example, a sum of a threshold Vt3 of the second plurality of GaN based gate-to-source shorted transistors 304 and a threshold Vt2 of the first GaN based shunt transistor 108 (within a second state 604). When the first ESD protection path 510 is triggered, a divisional bias 514 is applied on the gate terminal of the second GaN based shunt transistor 308. A second ESD protection path 516 is triggered when the gate input voltage Vgs is greater than a second trigger threshold, where the divisional bias 514 is greater than a threshold Vt4 of the second GaN based shunt transistor 308 (within a third state 606). The second trigger threshold is a sum of the thresholds Vt3, Vt2 and Vt4.

FIG. 7 illustrates a graph 700 of gate voltage and protection current behaviors of the ESD protection circuit 300 of FIG. 3 and FIG. 5 in response to positive and negative gate input voltage overshooting in accordance with some embodiments. Solid lines 704a and 704b show examples of gate input voltages after an ESD spike striking the gate terminal of the gallium nitride (GaN) based transistor 102. The ESD protection circuit 300 reduces and clamps the gate input voltages to a sustainable level to protect the gate terminal from being damaged. Dashed lines 702a and 702b show protection currents that are shunted by the ESD protection circuit 300 and tend to reduce to almost zero within a period of time after the gate input voltage overshooting.

FIG. 8 illustrates an electrostatic discharge (ESD) protection circuit 800 integrated with a gallium nitride (GaN) based transistor 102 in accordance with some alternative embodiments. In some embodiments, the ESD protection circuit 800 includes a number of subsections 802a, 802b . . . connected in series. Each of the subsections can have a plurality of GaN based gate-to-source shorted transistors and a resistor connected in series. In some embodiments, the subsections may have the same components arranged in one direction as shown in 802a and 802b. In some other embodiments, the subsections may comprise back to back connected components as shown in FIG. 3 and FIG. 5. In some further embodiments, the number of GaN based gate-to-source shorted transistors in different subsections can be different, to provide for an optimal protection result. For example, first subsection 802a may have a first number of GaN based gate-to-source shorted transistors and second subsection 802b may have a second number of GaN based gate-to-source shorted transistors which is greater than or less than the first number. In some alternative embodiments, the GaN based transistor 102 can be a depletion mode HEMT.

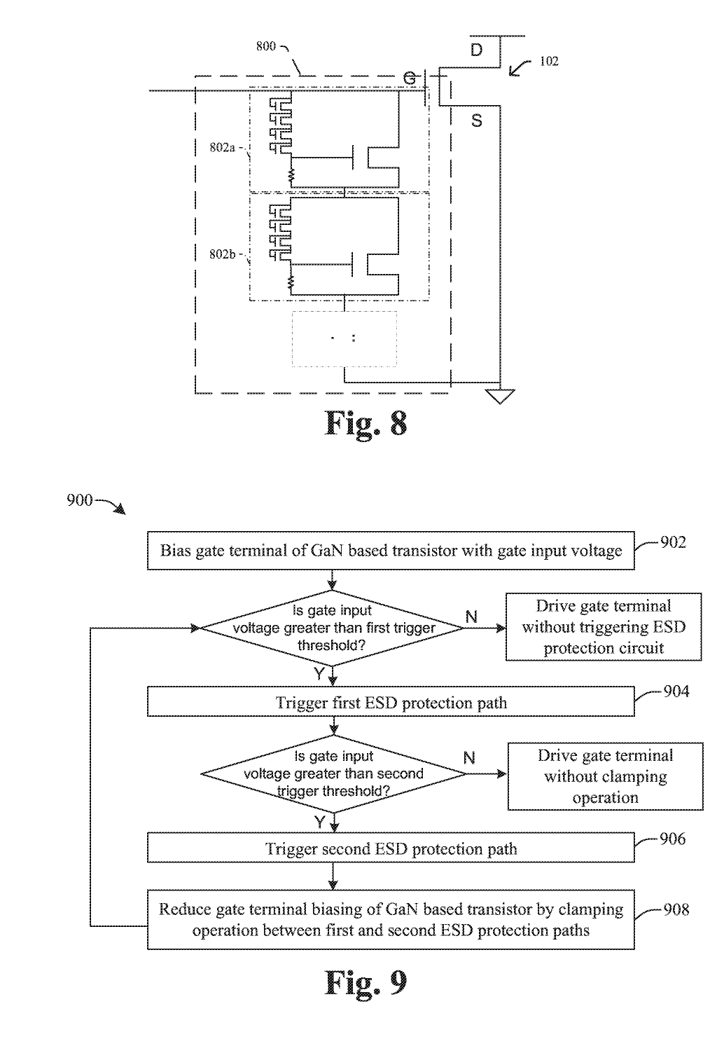

FIG. 9 illustrates a flow diagram illustrating a method 900 of protecting a gate terminal of a GaN based transistor during an ESD surge event in accordance with some embodiments. The method 900 triggers a first ESD protection path and a second ESD protection path when a gate input voltage exceeds a trigger threshold. Gate terminal of the GaN based transistor is protected from damaging by reducing a gate input voltage and introducing a clamping process between the first and second ESD protection paths.

The operation cycle starts at block 902, wherein a gate terminal of a GaN based transistor is biased with a gate input voltage. If the gate input voltage is around a desired operation gate voltage or within a maximum strike value allowed, the gate terminal is driven without triggering an ESD protection circuit. Almost no protection current flows through the ESD protection circuit. The first state 202 in FIG. 2 shows an example of this operation state.

At block 904, the first ESD protection path is triggered if the gate input voltage is greater than a first trigger threshold. If the gate input voltage is not greater than a second trigger threshold, some current will shunt through the first ESD protection path, but the second protection path is not triggered. The second state 204 in FIG. 2 shows an example of this operation state.

At block 906, the second ESD protection path is triggered if the gate input voltage is greater than a second trigger threshold. The second trigger threshold is greater than the first trigger threshold. The third state 206 in FIG. 2 shows an example of this operation state.

At block 908, the gate terminal biasing of the GaN based transistor is reduced by a clamping operation between the first and second ESD protection paths. The third state 206 in FIG. 2 shows an example of this operation state. The clamping effect can also be referred to FIG. 7 as an example.

It will be appreciated that while reference is made throughout this document to exemplary structures in discussing aspects of methodologies described herein (e.g., the structure presented in FIG. 2, while discussing the example set forth in FIG. 3), that those methodologies are not to be limited by the corresponding structures presented. Rather, the methodologies (and structures) are to be considered independent of one another and able to stand alone and be practiced without regard to any of the particular aspects depicted in the Figures.

Also, equivalent alterations and/or modifications may occur to those skilled in the art based upon a reading and/or understanding of the specification and annexed drawings. The disclosure herein includes all such modifications and alterations and is generally not intended to be limited thereby. For example, although the figures provided herein, are illustrated and described to have a particular function block, it will be appreciated that alternative separate blocks may be utilized as will be appreciated by one of ordinary skill in the art.

Thus, the present disclosure relates to voltage regulation techniques. Voltage regulation systems or voltage regulation methods of some embodiments are disclosed. By employing an accumulation of weighted digital error signals at present and some previous operation cycles, the voltage regulation is performed in a digital world utilizing a very simple configuration. A wide power range, including different voltage domains and dramatic current change rate variation can be addressed universally without separate conditional routines or additional hardware. Also, response can be adjusted easily by changing weighting coefficient values, which makes design more flexible.

In some embodiments, the present disclosure relates to an electrostatic discharge (ESD) protection circuit integrated with a gallium nitride (GaN) based transistor. The ESD protection circuit comprises a first ESD protection stage connected between a gate terminal and a source terminal of the GaN based transistor and comprising a first plurality of GaN based gate-to-source shorted transistors connected in series and further connected to a first terminal of a first resistor. The ESD protection circuit further comprises a second ESD protection stage connected to the first ESD protection stage in parallel and comprising a first GaN based shunt transistor having a gate terminal connected to the first terminal of the first resistor.

In some other embodiments, the present disclosure relates to an electrostatic discharge (ESD) protection circuit integrated with a gallium nitride (GaN) based transistor and configured to protect a gate terminal of the GaN based transistor during an ESD surge event. The ESD protection circuit comprises a first ESD protection stage comprising a first ESD protection path between a gate terminal and a source terminal of the GaN based transistor, configured to be biased by a gate input voltage of the GaN based transistor. The first ESD protection path is triggered when the gate input voltage is greater than a first trigger threshold. The ESD protection circuit further comprises a second ESD protection stage operably associated with the first ESD protection stage, comprising a second ESD protection path between the gate terminal and the source terminal of the GaN based transistor, the second ESD protection path being triggered when the gate input voltage is greater than a second trigger threshold. The gate input voltage of the GaN based transistor is reduced during the ESD surge event.

Still in some other embodiments, the present disclosure relates to a method of protecting a gate terminal of a GaN based transistor during an ESD surge event. The method comprises biasing the gate terminal of the GaN based transistor with a gate input voltage and triggering a first ESD protection path in response to the gate input voltage that is greater than a first trigger threshold. The method further comprises triggering a second ESD protection path that being associated with the first ESD protection path, in response to the gate input voltage that is greater than a second trigger threshold and reducing the gate input voltage through a clamping process between the first ESD protection path and the second ESD protection path.

While a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein, such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein.

What is claimed is:

1. An electrostatic discharge (ESD) protection circuit integrated with a gallium nitride (GaN) based transistor, the ESD protection circuit comprising:
a first ESD protection stage connected between a gate terminal and a source terminal of the GaN based transistor and comprising a first plurality of GaN based gate-to-source shorted transistors connected in series and further connected to a first terminal of a first resistor; and
a second ESD protection stage connected to the first ESD protection stage in parallel and comprising a first GaN based shunt transistor having a gate terminal connected to the first terminal of the first resistor.

2. The ESD protection circuit of claim 1, wherein the GaN based transistor is an enhancement mode high electron mobility transistor (E-HEMT).

3. The ESD protection circuit of claim 1, wherein the first GaN based shunt transistor has a first S/D terminal connected to the gate terminal of the GaN based transistor.

4. The ESD protection circuit of claim 1, wherein the first GaN based shunt transistor has a second S/D terminal connected to the source terminal of the GaN based transistor.

5. The ESD protection circuit of claim 1, wherein the first resistor has a second terminal connected to the source terminal of the GaN based transistor.

6. The ESD protection circuit of claim 1, wherein a first GaN based gate-to-source shorted transistor of the first plurality of GaN based gate-to-source shorted transistors has its gate terminal and first S/D terminal connected to the gate terminal of the GaN based transistor, and its second S/D terminal connected to a gate terminal and a first S/D terminal of a second GaN based gate-to-source shorted transistor of the first plurality of GaN based gate-to-source shorted transistors.

7. The ESD protection circuit of claim 1, wherein each of the first plurality of GaN based gate-to-source shorted transistors has a channel width that is 10 to 50 times smaller than a channel width of the first GaN based shunt transistor.

8. The ESD protection circuit of claim 1, wherein each of the first plurality of GaN based gate-to-source shorted transistors has a channel width that is smaller than a channel width of the first GaN based shunt transistor.

9. The ESD protection circuit of claim 1,
wherein the first ESD protection stage further comprises a second plurality of GaN based gate-to-source shorted transistors connected in series and between the source terminal of the GaN based transistor and a first terminal of a second resistor, the second resistor having a second terminal connected to a second terminal of the first resistor;
wherein the second ESD protection stage further comprises a second GaN based shunt transistor having a gate terminal connected to the first terminal of the second resistor.

10. The ESD protection circuit of claim 9, wherein a first GaN based gate-to-source shorted transistor of the second plurality of GaN based gate-to-source shorted transistors has a gate terminal shorted to a first S/D terminal and connected to the source terminal of the GaN based transistor, and a second S/D terminal connected to a shorted gate terminal and a first S/D terminal of a second GaN based gate-to-source shorted transistor of the second plurality of GaN based gate-to-source shorted transistors.

11. An electrostatic discharge (ESD) protection circuit integrated with a gallium nitride (GaN) based transistor and configured to protect a gate terminal of the GaN based transistor during an ESD surge event, the ESD protection circuit comprising:
a first ESD protection stage comprising a first ESD protection path between a gate terminal and a source terminal of the GaN based transistor, configured to be biased by a gate input voltage of the GaN based transistor, wherein the first ESD protection path is triggered when the gate input voltage is greater than a first trigger threshold; and
a second ESD protection stage operably associated with the first ESD protection stage, comprising a second ESD protection path between the gate terminal and the source terminal of the GaN based transistor, the second ESD protection path being triggered when the gate input voltage is greater than a second trigger threshold;
wherein the gate input voltage of the GaN based transistor is reduced during the ESD surge event.

12. The ESD protection circuit of claim 11, wherein when the gate input voltage is greater than the second trigger threshold, the gate input voltage is clamped through a clamping process between the first ESD protection path and the second ESD protection path.

13. The ESD protection circuit of claim 11, wherein the second ESD protection stage is configured to be controlled by a divisional bias of the first ESD protection stage.

14. The ESD protection circuit of claim 11, wherein the second ESD protection stage is configured to be triggered by a reversed bias greater than a reverse trigger threshold.

15. The ESD protection circuit of claim 11,
wherein the first ESD protection stage comprises a first plurality of GaN based gate-to-source shorted transistors connected in series;
wherein the first trigger threshold is a sum of thresholds of the first plurality of GaN based gate-to-source shorted transistors.

16. The ESD protection circuit of claim 15,
wherein the second ESD protection stage comprises a first GaN based shunt transistor having a gate terminal coupled to the first ESD protection stage.

17. The ESD protection circuit of claim 16,
wherein the second trigger threshold is greater than the first trigger threshold by a threshold of the first GaN based shunt transistor.

18. The ESD protection circuit of claim 16, further comprising:
a second GaN based shunt transistor in series with the first GaN based shunt transistor and configured to be controlled by a second divisional bias of the first ESD protection stage;
wherein the first trigger threshold is a sum of thresholds of the first plurality of GaN based gate-to-source shorted transistors and a threshold of the second GaN based shunt transistor.

19. The ESD protection circuit of claim 18, further comprising:
a second plurality of GaN based gate-to-source shorted transistors in series with the first plurality of GaN based gate-to-source shorted transistors and configured to control the second GaN based shunt transistor;
wherein a reverse trigger threshold that triggers a reverse ESD protection path is a sum of thresholds of the second plurality of GaN based gate-to-source shorted transistors and a threshold of the first GaN based shunt transistor.

20. A method of protecting a gate terminal of a GaN based transistor during an ESD surge event, comprising:
biasing the gate terminal of the GaN based transistor with a gate input voltage;
triggering a first ESD protection path in response to the gate input voltage that is greater than a first trigger threshold;
triggering a second ESD protection path that being associated with the first ESD protection path, in response to the gate input voltage that is greater than a second trigger threshold; and
reducing the gate input voltage through a clamping process between the first ESD protection path and the second ESD protection path.
